(19) United States
(12) Patent Application Publication
(10) Pub. No.: US 2016/0079370 A1
(43) Pub. Date: Mar. 17, 2016

(54) SEMICONDUCTOR DEVICE, SEMICONDUCTOR WAFER, AND SEMICONDUCTOR DEVICE MANUFACTURING METHOD

(71) Applicant: KABUSHIKI KAISHA TOSHIBA, Tokyo (JP)

(72) Inventors: Naoharu SUGIYAMA, Komatsu Ishikawa (JP); Kunio TSUDA, Nonoichi Ishikawa (JP)

(21) Appl. No.: 14/633,685

(22) Filed: Feb. 27, 2015

(30) Foreign Application Priority Data
Sep. 12, 2014 (JP) 2014-186400

(51) Int. Cl. H01L 29/20; H01L 21/02; H01L 29/207; H01L 29/36; H01L 29/32; H01L 29/06

(52) U.S. Cl. CPC H01L 29/2003; H01L 29/32; H01L 29/0649; H01L 29/207; H01L 29/36; H01L 21/0242; H01L 21/0245; H01L 21/02513; H01L 21/0254; H01L 21/02694

(57) ABSTRACT

According to one embodiment, a nitride semiconductor device including a first semiconductor layer and a second semiconductor layer is provided. The first semiconductor layer is provided on a base, and includes a nitride semiconductor. The first semiconductor layer includes a first region, and a second region which is provided on the first region, has a concentration of Si lower than a concentration of Si in the first region, and is thicker than the first region. The second semiconductor layer is provided on the first semiconductor layer.

### CROSS-REFERENCE TO RELATED APPLICATION

This application is based upon and claims the benefit of priority from Japanese Patent Application No. 2014-186400, filed Sep. 12, 2014, the entire contents of which are incorporated herein by reference.

### FIELD

Exemplary embodiments described herein relate generally to a semiconductor device, a semiconductor wafer, and a semiconductor device manufacturing method.

### BACKGROUND

A nitride semiconductor is used as a material for a high frequency device, a light emitting device, a light receiving device, or the like. A semiconductor device including such devices is manufactured using a semiconductor wafer having a nitride semiconductor crystal layer. For example, the nitride semiconductor crystal layer is formed on a substrate using silicon as abase substrate on which the nitride semiconductor is formed. There is a great difference in lattice constants and thermal expansion coefficients of the silicon substrate material and the nitride semiconductor layer grown thereon. Therefore, crystal defects and stresses occur in the nitride semiconductor crystal layer, such that the crystal quality is reduced and the life and productivity of the resulting nitride semiconductor based devices are impaired.

### DESCRIPTION OF THE DRAWINGS

FIG. 1 is a schematic cross-sectional view illustrating a semiconductor device according to a first embodiment.

FIG. 2 is a graph illustrating an element distribution of a stacked structure of a nitride semiconductor according to the first embodiment.

FIGS. 3A and 3B are schematic cross-sectional views illustrating a second semiconductor layer.

FIG. 4 is a flowchart illustrating a semiconductor device manufacturing method according to the first embodiment.

FIGS. 5A and 5B are schematic cross-sectional views illustrating a part of the semiconductor device manufacturing method according to the first embodiment.

FIGS. 6A and 6B are schematic cross-sectional views illustrating a part of the semiconductor device manufacturing method according to the first embodiment.

FIGS. 7A and 7B are schematic cross-sectional views illustrating a part of a semiconductor device manufacturing method according to a second embodiment.

FIGS. 8A to 8C are schematic cross-sectional views illustrating a part of the semiconductor device manufacturing method according to the second embodiment.

### DETAILED DESCRIPTION

Exemplary embodiments provide a semiconductor device, a semiconductor wafer, and a semiconductor device manufacturing method, in which the crystal quality of a nitride semiconductor is enhanced.

In general, according to one embodiment, there is provided a nitride semiconductor device including a first semiconductor layer and a second semiconductor layer. The first semiconductor layer is provided on a base and includes a nitride semiconductor. The first semiconductor layer includes a first region and a second region. The second region is provided on the first region, has a lower Si concentration than the Si concentration in the first region, and is thicker than the first region. The second semiconductor layer is provided on the first semiconductor layer.

Hereinafter, exemplary embodiments will be described below with reference to the drawings.

In addition, the drawings are schematic or conceptual, and a relationship between the thicknesses and the widths of respective portions, the ratios of the sizes of the portions, and the like are not necessarily equal to those in an actual element or device. Further, when representing the same portion(s) of an element or device, the portion may be represented having different dimensions and ratios in the different drawings.

In addition, in this specification and respective drawings, the same components as components illustrated in the previous drawings are denoted by the same reference numerals in later drawings, and thus the detailed description thereof is appropriately omitted.

### First Embodiment

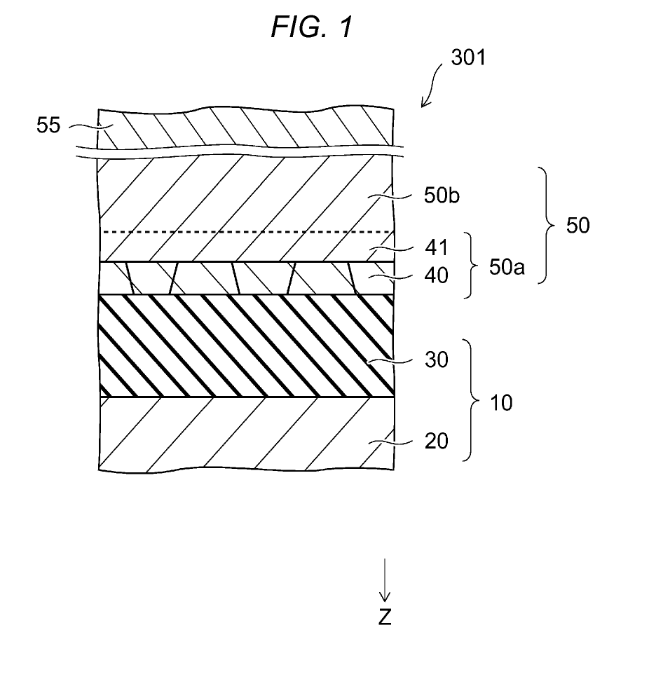

FIG. 1 is a schematic cross-sectional view illustrating a semiconductor device according to a first embodiment.

A semiconductor device 301 is, for example, a light emitting diode (LED), a high electron mobility transistor (HEMT), or the like.

As illustrated in FIG. 1, the semiconductor device 301 according to the first embodiment includes a base 10, a first semiconductor layer 50, and a second semiconductor layer 55.

10 includes a substrate 20 and a first layer 30. As a material of the substrate 20, polycrystalline aluminum nitride (AlN) is used. The thickness of the substrate 20 is 200 μm or more and 1000 μm or less.

The first layer 30 is provided on the substrate 20. As a material of the first layer 30, silicon oxide (SiO₂) is used. The thickness of the first layer 30 is 5 nm or more and 1000 nm or less.

The first semiconductor layer 50 is provided on the base 10. The first semiconductor layer 50 is a single crystal. Gallium nitride (GaN) is used as the material of the first semiconductor layer 50. The thickness of the first semiconductor layer 50 is, for example, 1 μm or more and 10 μm or less.

The first semiconductor layer 50 includes a first region 50a and a second region 50b. The first region 50a is in contact with the first layer 30. The first region 50a is a single crystal, and includes GaN and silicon (Si).

The first region 50a may include a nitride crystal layer 41 and a silicon crystal layer 40. In this case, the silicon crystal layer 40 is in contact with the first layer 30. The nitride crystal layer 41 is provided on the silicon crystal layer 40.

The second region 50b is provided on the first region 50a. The second region 50b is a single crystal, and includes GaN. Further, the second region 50b may include Si.

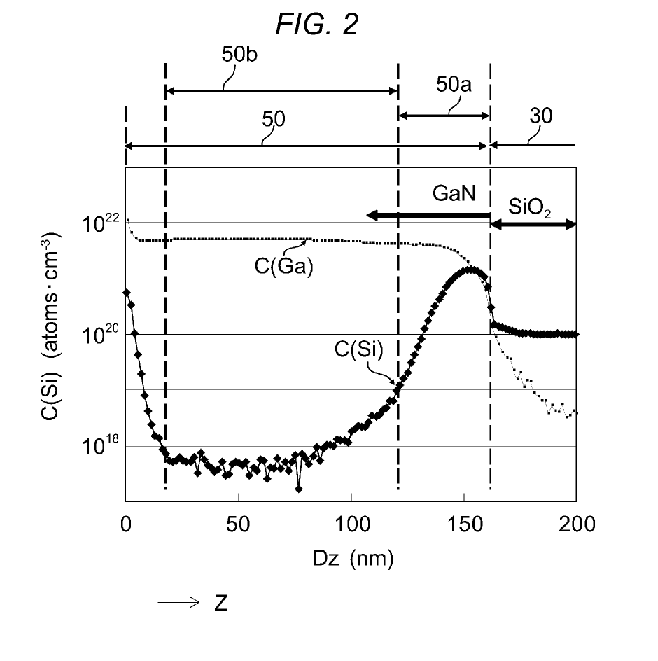

FIG. 2 is a graph illustrating the distribution of elements in a stacked structure of a nitride semiconductor according to the first embodiment. The concentration distribution of Si by depth is measured by a secondary ion mass spectrometry (SIMS) method.

A horizontal axis in FIG. 2 represents a position Dz along the Z-axis direction (a direction from the first semiconductor layer 50 to the base 10). A vertical axis in FIG. 2 represents a concentration of Si (C(Si) (atoms·cm⁻³)).

The concentration of Si in the first region 50a is, for example, 1×10¹⁹ (atoms·cm⁻³) or more. The thickness of the first region 50a is 5 nm or more and 500 nm or less.

The concentration of Si in the second region 50b is lower than the concentration of Si in the first region 50a. The concentration of Si in the second region 50b is, for example, 1×10¹⁹ (atoms·cm⁻³) or less. The thickness of the second region 50b is 50 nm or more and 10 μm or less.

The second semiconductor layer 55 is provided on the first semiconductor layer 50. The second semiconductor layer 55 includes single crystal nitride semiconductor. The second semiconductor layer 55 has at least one of a light emitting function, a light receiving function, and a current switching function.

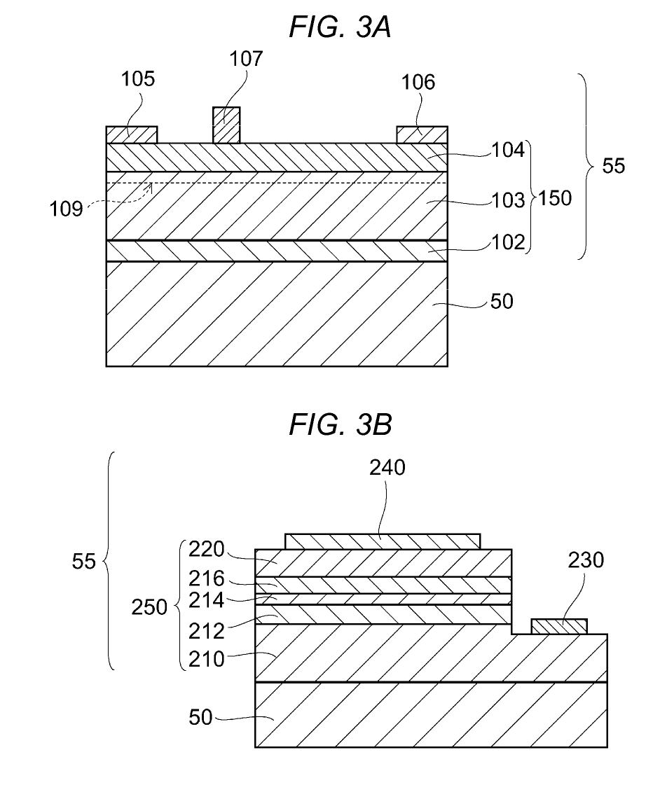

FIGS. 3A and 3B are schematic cross-sectional views illustrating a use of the second semiconductor layer 55.

FIG. 3A illustrates a case in which the semiconductor device 301 is a GaN-based HEMT. In this case, the second semiconductor layer 55 includes a semiconductor stacked body 150, a source electrode 105, a drain electrode 106, and a gate electrode 107.

The semiconductor stacked body 150 includes a buffer layer 102, a semiconductor layer 103 (first semiconductor film), and a semiconductor layer 104 (second semiconductor film).

The buffer layer 102 is provided on the first semiconductor layer 50. A GaN layer, an AlN layer or an AlGaN layer is used as the material of the buffer layer 102. In addition, the buffer layer 102 is not necessarily required, so it may be omitted. Further, the thickness of the buffer layer 102 may be 100 μm or more. In particular, since there is a small difference between the thermal expansion coefficients of the buffer layer 102 and that of the substrate 20, there is no substantially restriction in the thickness.

The semiconductor layer 103 is provided on the buffer layer 102. The semiconductor layer 103 is a channel layer, and includes undoped Al_{α}Ga_{1-α}N (0≦α≦1).

The semiconductor layer 104 is provided on the semiconductor layer 103. The semiconductor layer 104 is a barrier layer, and includes undoped or n-type Al_{β}Ga_{1-β}N (0≦β≦1, α<β). The band gap of the semiconductor layer 104 is greater than the band gap of the semiconductor layer 103. The semiconductor layer 103 and the semiconductor layer 104 form a heterojunction.

The source electrode 105 and the drain electrode 106 are respectively provided on the semiconductor layer 104. The source electrode 105 and the drain electrode 106 are spaced from each other along the second semiconductor layer 104. The source electrode 105 and the drain electrode 106 are each electrically connected to the semiconductor layer 104 so as to form Ohmic contact therewith.

The gate electrode 107 is provided between the source electrode 105 and the drain electrode 106, and spaced from the semiconductor layer 104 by gate insulating film on the surface of the semiconductor layer 104. Alternatively, the gate electrode 107 may be in Schottky contact with the surface of the semiconductor layer 104.

The lattice constant of the semiconductor layer 104 is smaller than the lattice constant of the semiconductor layer 103. Therefore, a strain occurs in the semiconductor layer 104, and a piezoelectric polarization occurs in the semiconductor layer 104, due to the piezoelectric effect. Thus, two-dimensional electron gas region is formed in the vicinity of the interface of the semiconductor layer 103 and the semiconductor layer 104. A concentration of the two-dimensional electron gas region below the gate electrode 107 increases or decreases and the current flowing between the source electrode 105 and the drain electrode 106 is controlled, by controlling the gate voltage applied to the gate electrode 107.

FIG. 3B shows a case in which the semiconductor device 301 is a GaN-based LED. In this case, the second semiconductor layer 55 includes a semiconductor stacked body 250, an n-side electrode 230, and a p-side electrode 240.

The semiconductor stacked body 250 includes an n-type GaN layer (n-type semiconductor layer) 210, an n-type GaN guide layer 212, an active layer 214, a p-type GaN guide layer (p-type semiconductor layer) 216, and a p-type GaN layer 220.

The n-type GaN layer 210 is provided on the first semiconductor layer 50.

The n-type GaN guide layer 212 is provided on the GaN layer 210. A part of the surface of the n-type GaN layer 210 is exposed.

The active layer 214 is provided on the n-type GaN guide layer 212. The active layer 214 includes InGaN, for example, has a Multi-Quantum Well (MQW) structure in which a In_{0.15}Ga_{0.85}N layer and a In_{0.02}Ga_{0.98}N layer are stacked.

The p-type GaN guide layer 216 is provided on the active layer 214.

The p-type GaN layer 220 is provided on the p-type GaN guide layer 216.

The n-side electrode 230 is provided on the exposed portion of the n-type GaN layer 210. The p-side electrode 240 is provided on the p-type GaN layer 220.

When a predetermined voltage is applied between the n-side electrode 230 and the p-side electrode 240, holes and electrons recombine in the active layer 214, and for example, blue light is emitted from the active layer 214. The light emitted from the active layer 214 is extracted from the first semiconductor layer 50 side or the p-side electrode 240 side.

Next, a semiconductor device manufacturing method according to the present embodiment will be described.

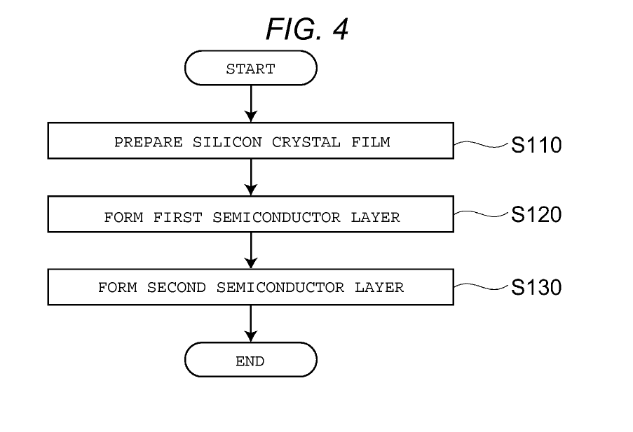

FIG. 4 is a flowchart illustrating the semiconductor device manufacturing method according to the first embodiment.

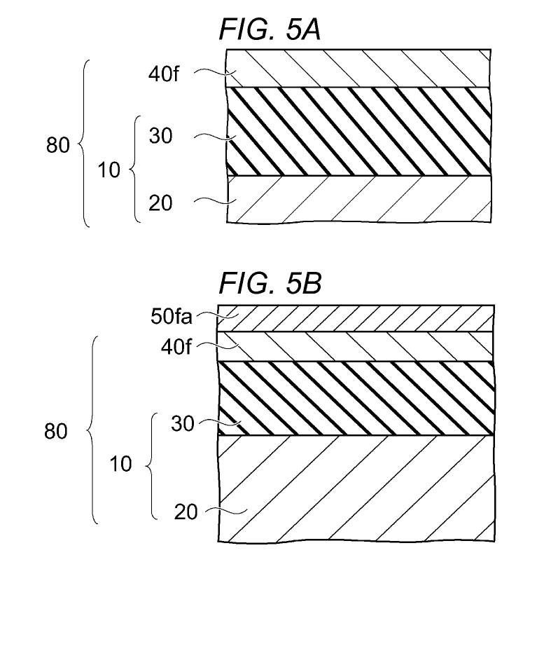

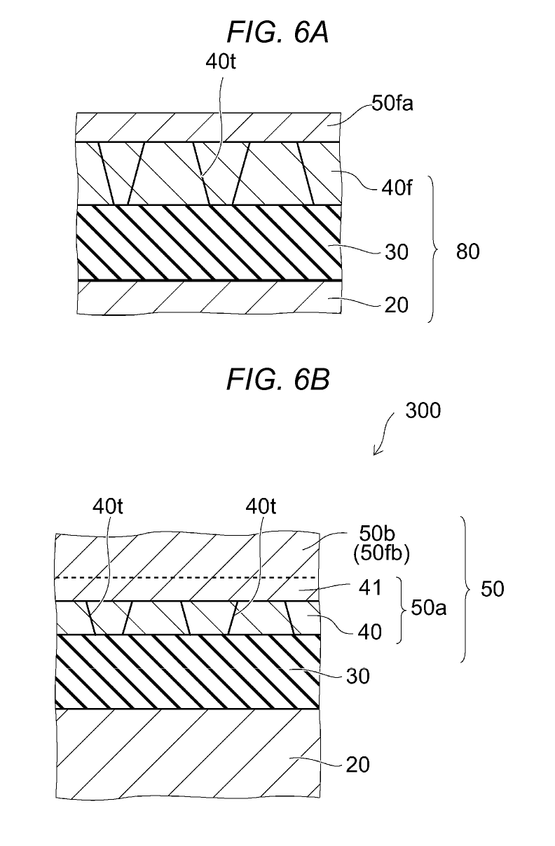

FIGS. 5A to 6B are schematic cross-sectional views illustrating a part of the semiconductor device during the steps of manufacturing the device according to the first embodiment.

As illustrated in FIG. 4, the semiconductor device manufacturing method according to the embodiment includes steps S110, S120 and S130.

In step S110, as illustrated in FIG. 5A, a silicon crystal film 40f (ultra-thin Si layer) provided on the base 10 is prepared.

The thickness of the silicon crystal film 40f is, for example, 2 nm or more and 30 nm or less. The crystal orientation of the surface of the silicon crystal film 40f is a (111). The silicon crystal film 40f is a film of which at least a part is incorporated into the first region 50a described above.

The base 10 includes a first layer 30 (SiO₂ layer) provided on the substrate 20 (a polycrystalline AlN substrate). In other words, a processing body 80 (wafer) having a structure of an ultra-thin Si layer/a SiO₂ layer/a polycrystalline AlN layer is prepared.

Here, it is possible to obtain an ultra-thin layer of a thickness of 10 nm or less by oxidizing the surface layer through thermal oxidization, and then thinning the silicon crystal film 40f. It is possible to easily remove the surface oxide film after thermal oxidation through hydrofluoric acid treatment. Also, even if the thermal oxide film is not attached to the surface, a sample substrate is treated with a dilute hydrofluoric acid solution of a concentration of about 1% for about one minute in order to perform the hydrogen termination process on the surface of the substrate. Through this process, the surface of the silicon crystal film 40f has a surface structure which is terminated with hydrogen and is water repellent.

Next, in step S120, the first semiconductor layer 50 is formed by stacking a nitride semiconductor film on the silicon crystal film 40f of which the surface is subjected to the hydrogen termination process. The first semiconductor layer 50 is formed in the following manner.

First, the processing body 80 is introduced to an MOCVD (metal-organic chemical vapor deposition) reactor, and the processing body 80 temperature is raised to 500° C. Then, as shown in FIG. 5B, a nitride semiconductor film 50fa (gallium nitride crystal layer) is epitaxially grown, using trimethylgallium (TMG) and ammonia (NH₃) as gaseous source materials. The nitride semiconductor film 50fa is a film that is a part of the first region 50a. The thickness of the nitride semiconductor film 50fa is, for example, 20 nm.

Next, the temperature of the processing body 80 is raised to 1080° C. At this time, dislocation 40t and plastic deformation occur in the ultra-thin silicon crystal film 40f, due to the stress caused by a lattice mismatch between the nitride semiconductor film 50fa and the ultra-thin silicon crystal film 40f. In addition, the stress and strain that are applied to the nitride semiconductor film 50fa is released by plastic deformation of the ultra-thin silicon crystal film 40f. The state at this stage is schematically shown in FIGS. 6A and 6B. In the first region 50a, the dislocation density is larger than that of the second region 50b. The dislocation can be observed by using a transmission electron microscope.

Further, as shown in FIG. 6B, the nitride semiconductor film 50fb (a gallium nitride crystal layer) is formed on the nitride semiconductor film 50fa, at 1080° C. using an MOCVD process with gaseous trimethylgallium (TMG) and ammonia (NH₃) as source materials. The nitride semiconductor film 50fb becomes incorporated into the second region 50b. The thickness of the nitride semiconductor film 50fb is, for example, 2 μm.

At this stage, some or all of the silicon atoms in the ultra-thin silicon crystal film 40f react with the nitride semiconductor film 50fa. Thus, the first region 50a is formed. In this reaction, mutual inter-diffusion of gallium atoms and silicon atoms occurs, at least a part of the silicon crystal film 40f is incorporated into the nitride semiconductor film 50fa, and thus the thickness of the silicon crystal film 40f is reduced. In this manner, a silicon crystal layer 40 that is thinner than the silicon crystal film 40f also is formed. Alternatively, the ultra-thin silicon crystal film 40f disappears as a result of full incorporation into nitride semiconductor film 50fa.

In the nitride semiconductor film 50fa which is formed at low temperature (500° C.), lattice relaxation occurs when the temperature is raised to 1080° C. Even when the nitride semiconductor film 50fa is not fully relaxed and some strain remains at this stage, lattice relaxation further occurs at the stage of growing a nitride semiconductor film 50fb of 2 μm thickness thereon at a high temperature. Thus, the nitride semiconductor crystal layer in which lattice stress and strain are relaxed is obtained. As described above, the second region 50b is formed on the first region 50a, and a semiconductor wafer 300 having the first semiconductor layer 50 is formed.

Then, in step S130, the semiconductor device is completed by forming the second semiconductor layer 55 on the first semiconductor layer 50.

In addition, in the present embodiment, the metal-organic chemical vapor deposition method (a MOCVD method) is exemplified as a method of thin film crystal growth of the first semiconductor layer 50, but any of a molecular beam epitaxy (MBE) method and a hydride vapor phase epitaxy (HVPE) method may be used, which are also thin film crystal growth methods generally used for nitride semiconductor crystal growth.

In addition, when manufacturing a semiconductor devices which is represented by a light emitting diode (LED), n-type (Si) and p-type (Mg) may be doped on the first semiconductor layer 50. Generally, in order to form an n-type layer on the base substrate side, during the gallium nitride growth at 1080° C., doping is performed and silicon atoms of approximately 1×10¹⁸ (atoms·cm⁻³) may be added. However, during formation of the nitride semiconductor film 50fa on the ultra-thin silicon crystal film 40f as in the present embodiment, the gallium atoms in the nitride semiconductor film 50fa and the silicon crystal react, and silicon atoms diffuse into the nitride semiconductor crystal layer. Therefore, the thickness of the ultra-thin silicon crystal film 40f is reduced after the formation of the first semiconductor layer 50, or all of the ultra-thin silicon crystal film 40f disappears. Specifically, in the gallium nitride crystal layer (500 nm at the bottom of the growth layer) which is in contact with ultra-thin silicon crystal film 40f, silicon atoms of the concentration of 1×10¹⁹ (atoms·cm⁻³) or more and 1×10²⁰ (atoms·cm⁻³) or less is included, without performing doping by introducing monosilane gas during the growth.

However, in general, it is difficult to form a compound semiconductor crystal, especially, a nitride semiconductor crystal of a high quality on the silicon substrate.

For example, a reference example is one in which a nitride semiconductor crystal layer is directly epitaxially grown on the silicon crystal substrate having a thickness of 500 μm or more and 1000 μm or less. In this reference example, with an increase in the thickness of the grown nitride semiconductor crystal layer, stress and strain due to the lattice mismatch between the nitride semiconductor crystal and the silicon crystal increases. Eventually, a dislocation occurs on the nitride semiconductor crystal side in order to relax this stress. Thus, plastic deformation occurs, and accumulated stress is relaxed. As a result, a large amount of dislocation of about [symbol] (number·cm⁻²) remains in the nitride semiconductor crystal layer which is formed on the silicon crystal substrate. Thus, the quality of the nitride semiconductor crystal is reduced.

In general, the lattice constant of the compound semiconductor crystal differs from that of the silicon crystal. For example, since the lattice constants of the silicon crystal and the GaAs crystal are different by about 4%, when the GaAs crystal is epitaxially grown on the silicon substrate, lattice relaxation is caused as a result of dislocation in the GaAs crystal, and thus it is not possible to obtain a GaAs crystal of a high quality. In recent years, nitride semiconductor which consist of hexagonal crystalline structure attracts attention as a material of a light emitting devices, and the hexagonal crystal is different from the crystalline structure of a cubic crystal which can usually take on the crystalline structure of a silicon crystal, and the difference in the lattice constants becomes larger.

Further, as a reference example, it has been proposed that after a thin film silicon layer is prepared by interposing a fragile silicon crystal layer on a silicon substrate, a compound semiconductor crystal layer having a lattice mismatch is formed thereover. Specifically, a method is disclosed in which after a porous silicon layer is formed on the silicon substrate, flat ultra-thin layers are continuously formed on the surface, and then a compound semiconductor layer is epitaxially grown thereon.

Here, crystal defects caused by the lattice mismatch with silicon, or crystal defects caused by cooling to the room temperature from the film formation temperature and a difference between thermal expansion coefficients occur only in the ultra-thin silicon layer. However, in this method, it is difficult to form a flat ultra-thin layer on the surface under the condition in which the porosity of the porous layer is high (when a percentage of voids are high in a porous layer). Meanwhile, under the condition in which the porosity is as low as 20%, even if a flat ultra-thin layer is formed on the surface, a silicon crystal part is connected to the base in 80% of the area, and the percentage of the real ultra-thin part is 20%. Therefore, it is difficult to introduce defects for absorbing the strain caused by the lattice mismatch with the compound semiconductor crystal layer to be stacked with a good reproducibility.

Further, another method has been proposed in which epitaxial growth of a nitride semiconductor crystal layer is directly performed on the porous layer which is formed on a silicon substrate, and the porous layer can absorb a strain due to the lattice mismatch and a strain due to a difference of the thermal expansion coefficients, between the substrate and the nitride-based semiconductor. However, in this method, since the base part on which a compound semiconductor crystal layer is grown is not flat and crystal growth is started from respective protrusions which are exposed discontinuously in the porous layer surface, immediately after the start of the growth, independent crystals are formed and then joined in the horizontal direction. In this case, the silicon crystal as a base, and the compound semiconductor crystal subjected to the thin film growth, have different crystal forms as well as different lattice constants, and discontinuity occurs and defects are generated during the joining of respective crystals which are started to be grown independently.

In addition, when the nitride semiconductor layer is not formed on the ultra-thin silicon crystal but is formed on the normal silicon crystal portion, a large amount of silicon atoms may be diffused up to the entire area of the nitride semiconductor layer. Further, the bottom of the growth layer may attain a structure close to that of a mixed crystal of silicon and gallium nitride. Further, a silicon crystal portion may be eroded. In other words, after nitrogen is sublimated from the GaN crystal that is deposited on the silicon crystal at a high temperature and Ga atoms are extracted, a silicon crystal portion may be eroded and a cavity may be formed in the interface portion. Furthermore, silicon atoms that are extracted from the eroded silicon crystal portion diffuse into the GaN crystal in the top, and become n-type impurities of a high concentration, such that controllability of the conduction type is deteriorated.

In the present embodiment, the first semiconductor layer 50 has the first region 50a, and the second region 50b having a lower Si concentration than that of the first region 50a. The first semiconductor layer 50 is formed by preparing the ultra-thin silicon crystal film 40f which is uniformly thick enough to not be affected by the crystal property of the base, and growing the nitride semiconductor films (50fa and 50fb) which are thicker than the silicon crystal film 40f thereon. Then, during the growth of the nitride semiconductor films, a dislocation 40t (FIG. 6A) occurs on the ultra-thin silicon crystal film 40f side of the base. The stress and strain accompanied by the growth of the nitride semiconductor film is relaxed by the occurrence of the dislocation 40t. Thus, the occurrence of dislocations (crystal defects) in the second region 50b is suppressed, and it is possible to obtain a high-quality crystal layer.

When the thickness of the silicon crystal film 40f of the base is significantly greater than the thickness of the nitride semiconductor film to be epitaxially grown, a plastic deformation accompanying the occurrence of a dislocation to the base side of the layer stack rarely occurs. However, when the thickness of the silicon crystal film 40f of the base is significantly smaller than the thickness of the nitride semiconductor film, a plastic deformation accompanying the occurrence of a dislocation on the silicon crystal film 40f side of the base easily occurs. For example, the thickness of the first region 50a of the Si concentration of 1×10¹⁹ (atoms·cm⁻³) or more is 5 nm to 500 nm, the thickness of the second region 50b of the Si concentration of 1×10¹⁹ (atoms·cm⁻³) or less is in a range of 50 nm to 10 μm, and thus plastic deformation easily occurs.

It is possible to manufacture a high-performance semiconductor device by using a single crystal of a nitride semiconductor with a high quality having small defects. In order to epitaxially grow the nitride semiconductor crystal, typically, a material of the single crystal is used for the substrate. In this embodiment, the first layer 30 is provided on the substrate 20, and the silicon crystal film 40f of a uniform thickness is further provided thereon. By providing the first layer 30 in this manner, the silicon crystal film 40f, which is a base of epitaxial growth of the nitride semiconductor films 50fa and 50fb, is not affected by the crystal property of the material that is used for the substrate 20. Therefore, even if a polycrystalline material is used for the substrate 20, it is possible to obtain a high-quality crystal layer. In this embodiment, it is possible to use a substrate of a large diameter at a relatively low cost by using a polycrystalline AlN. In addition, it is possible to induce the plastic deformation accompanied by the occurrence of the dislocation 40t on the ultra-thin silicon crystal film 40f side, with good reproducibility.

When the difference between the thermal expansion coefficient of the material used for the substrate 20 and the thermal expansion coefficient of the material used for the first semiconductor layer 50 is large, or when the difference between the thermal expansion coefficient of the material used for the substrate 20 and the thermal expansion coefficient of the material used for the second semiconductor layer 55 is large, bowing may occur in the semiconductor device 301 due to changes in the temperature thereof. For example, the semiconductor device is periodically heated during the manufacture thereof, and generates heat during the operation. When the temperature of the semiconductor device rises due to the heat, a strain or bowing may occur in the device due to the difference between the thermal expansion coefficients of the different layers. When the bowing occurs in the semiconductor device, for example, the separation of an electrode is likely to occur, and this leads to a failure in the semiconductor device. In addition, even when heating or cooling during the manufacture of the semiconductor device, bowing or a crack may occur in the wafer, and thus crystal quality may decrease.

In contrast, in the embodiment, aluminum nitride (polycrystalline AlN) is used for the substrate 20. Therefore, a difference between the thermal expansion coefficient of the material used for the substrate 20 and the thermal expansion coefficient of the material used for the first semiconductor layer 50 (or the thermal expansion coefficient for the second semiconductor layer 55) is small (for example, less than 3×10⁻⁶K⁻¹). Thus, even if the temperature of the semiconductor device 301 changes, it is possible that the bowing due to the thermal expansion coefficient is suppressed.

Further, in the semiconductor device 301 according to the embodiment, the first layer 30 is provided between the substrate 20 and the first semiconductor layer 50. In other words, the first layer 30 (SiO₂ layer) having a small thermal expansion coefficient is interposed between the substrate 20 (AlN layer) and the first semiconductor layer 50 (GaN layer) which have a relatively large thermal expansion coefficient. Thus, the thermal contraction of the substrate 20 and the thermal contraction of the first semiconductor layer 50 (and the second semiconductor layer 55) are balanced, and thus it is possible to suppress the occurrence of bowing or a crack during the manufacture of the device.

In the present embodiment, the specific thicknesses of the stacked structure are respectively set as follows: polycrystalline AlN substrate (200 μm or more and 1000 μm or less), SiO₂ layer (5 nm or more and 1000 nm or less), and a first semiconductor layer 50 (50 nm or more and 10 μm or less). Thus, the contraction caused by the difference between the thermal expansion coefficients during manufacture and use is balanced by interposing the SiO₂ layer having a small heat contraction amount, and thus it is possible to suppress the occurrence of the bowing or crack.

During the formation of the nitride semiconductor crystal layer such as the first semiconductor layer 50 and the second semiconductor layer 55, when the layers are thick, the difference between the heat contraction amounts of the substrate 20 and the nitride semiconductor crystal layer increases. Therefore, the bowing caused by the thermal expansion coefficient easily occurs. In contrast, in the embodiment, since the difference between the thermal expansion coefficient of the material used for the substrate 20 and the thermal expansion coefficient of the nitride semiconductor crystal layer is small, it is possible to form thick first semiconductor layer 50 and second semiconductor layers 55 and maintain good quality. For example, in the example of HEMT illustrated in FIG. 3A, it is possible to increase the resistance in the vertical direction of the semiconductor layer and improve the breakdown voltage, by forming a thick second semiconductor layer 55.

In addition, it is possible to enhance the heat dissipation of the semiconductor device by using aluminum nitride having high thermal conductivity for the substrate 20. In the embodiment, the thermal conductivity of the substrate 20 is higher than the thermal conductivities of the first semiconductor layer 50 and the first layer 30. Thus, heat dissipation is efficiently performed through the substrate 20, and an increase in temperature is suppressed during the use of the semiconductor device. Therefore, it is possible to suppress bowing of the semiconductor device due to the difference between the thermal expansion coefficients.

Further, in the embodiment, the silicon crystal film 40f is stacked on a first layer 30 having a low reactivity for III group elements such as gallium (Ga) and indium (In). Then, the nitride semiconductor films (50fa and 50fb) are stacked thereon. The nitride semiconductor film is sufficiently thicker than the silicon crystal film 40f. Therefore, melt back etching of the silicon crystal film 40f by the III group elements is limited.

In other words, according to the present embodiment, since the thickness of the ultra-thin silicon crystal film 40f is 30 nm or less, even when the nitride semiconductor film 50fa is stacked on the ultra-thin silicon crystal film 40f at a low temperature and processed at a high temperature, the thickness of a region to be eroded by III group elements is the thickness (30 nm) of the ultra-thin silicon crystal film 40f or less at maximum. The total amount of silicon atoms diffusing into the first semiconductor layer 50 is limited, and it is possible to reduce the influence on the conduction type control of the first semiconductor layer 50.

### Second Embodiment

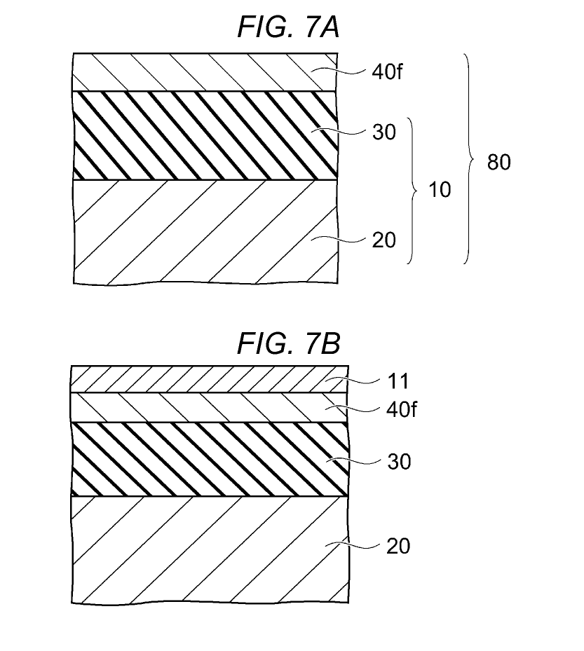

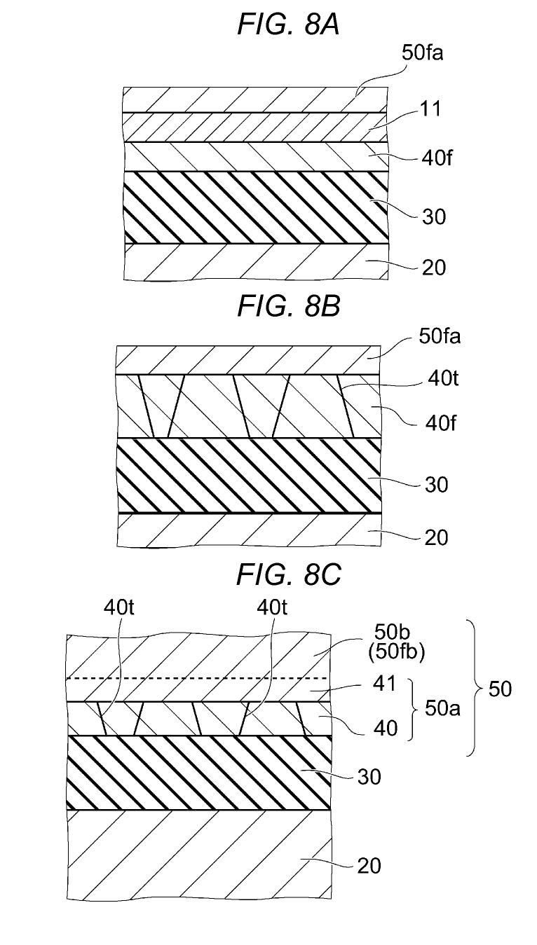

FIGS. 7A to 8C are schematic cross-sectional views illustrating a part of the semiconductor device manufacturing method according to second embodiment.

As shown in FIG. 7A, the processing body 80 is prepared. For example, the thickness of the substrate 20 is 650 μm, the thickness of the first layer 30 which is a buried oxide film layer is 200 nm, and the thickness of the ultra-thin silicon crystal film 40f on the top is 10 nm. Polycrystalline AlN is used for the substrate 20. The crystal surface of the silicon crystal film 40f on the surface is a (111) surface.

In general, the surface of the silicon layer exposed to air is rapidly covered with a natural oxide film (SiO₂) of about 1 nm to a few nm thickness. When epitaxially growing a thin film crystal on the silicon layer of which the surface is covered with a natural oxide film, it is necessary to expose the underlying crystal surface by removing the natural oxide film in the film formation device before the process of epitaxial growth. Typically, a method is used which removes the natural oxide film, by heating it at a high temperature of about 1000° C., in a non-oxidizing atmosphere, for example, in an atmosphere of nitrogen or hydrogen. However, when the silicon layer is an ultra-thin film of the thickness of about 10 nm, it is known that the thin film silicon layer can become agglomerated during a high-temperature heat treatment at about 1000° C., flatness (surface smoothness) of the layer is significantly impaired, or a Si layer deforms, or the silicon layer evaporates. Therefore, attention is required for the epitaxial growth on the ultra-thin silicon layer.

A hydrogen termination method is employed when performing the epitaxial growth on the ultra-thin silicon layer. In a structure in which the crystal surface of silicon is covered with hydrogen, it is possible to protect relatively stably a surface of the ultra thin silicon layer 40f in the atmosphere. Hydrogen atoms covering the surface are separated at a temperature of about 600° C., but it is possible to prevent a natural oxidation film forming on the silicon surface from room temperature to about 500° C. In other words, it is possible to perform epitaxial growth on the silicon layer at 500° C. while preventing oxidation on the silicon layer of which surface is terminated with hydrogen. Since it is possible to prevent the agglomeration of the ultra-thin silicon layer at the temperature of this level, it is possible to epitaxially grow a crystal layer such as GaN even on the ultra-thin silicon layer.

In order to apply the hydrogen termination process on the surface of the silicon crystal film 40f, treatment is performed with a dilute hydrofluoric acid solution of concentration of about 1% for about 1 minute. The surface of the ultra-thin silicon crystal film is terminated with hydrogen through this process, and this results in a water repellant surface. Successively, on the silicon crystal film 40f, of which the surface was subjected to the hydrogen termination process, the nitride semiconductor film 50fa (gallium nitride crystal layer which is a nitride semiconductor crystal layer) is subjected to thin film crystal growth (epitaxial growth).

For example, as shown in FIG. 7B, after a sample substrate is introduced into a MOCVD (metal-organic chemical vapor deposition method using an organic metal) device and a substrate temperature is raised to 500° C., three atomic layer equivalent gallium atoms are deposited on the surface of the ultra-thin silicon crystal film 40f, by supplying the sample substrate only with TMG before low temperature growth of a nitride semiconductor crystal layer. Thus, a gallium atom layer 11 is formed. At this stage, some of the gallium atoms are diffused into the ultra-thin silicon crystal film 40f.

Subsequently, as shown in FIG. 8A, the nitride semiconductor layer 50fa of 20 nm is formed by MOCVD, with trimethylgallium (TMG) and ammonia (NH₃) as the source materials.

Then, as shown in FIG. 8B, the wafer is heated to 1080° C. At this time, dislocations 40t occur in the silicon crystal film 40f side due to a stress caused by lattice mismatch between the nitride semiconductor film 50fa and the ultra-thin silicon crystal film 40f, and thus plastic deformation occurs therein. Further, the stress and strain applied to the nitride semiconductor film 50fa is released by the plastic deformation of the silicon crystal film 40f.

When the dislocation which occurs in the silicon crystal film surface (growth interface of the nitride semiconductor crystal layer) penetrates the silicon crystal film to the first layer interface, plastic deformation is likely to occur. Accordingly, in the embodiment, the thickness of the silicon crystal film 40f becomes the thickness at which gallium atoms can easily diffuse therethrough.

Further, in the first embodiment, the introduction of the III group atoms is not performed prior to the growth of the nitride semiconductor crystal. However, when the gallium nitride crystal layer is grown on the silicon crystal film, silicon atoms and gallium atoms diffuse into respective layers by the reaction occurring at the interface. Therefore, even in the first embodiment, it is considered that gallium atoms diffuse into the silicon crystal film.

Subsequently, as shown in FIG. 8C, at 1080° C., a nitride semiconductor film 50fb of 2 μm (a gallium nitride crystal layer that is a nitride semiconductor crystal layer) is formed by MOCVD, using trimethylgallium (TMG) and ammonia (NH₃) as the source materials.

Further, at this stage, some or all of the silicon atoms configuring the ultra-thin silicon crystal film 40f react with the nitride semiconductor film, mutual inter-diffusion of gallium atoms with silicon atoms occurs, and silicon atoms enter the nitride semiconductor crystal. Thus, the thickness of the ultra-thin silicon crystal film 40f decreases. In this manner, a silicon crystal layer 40 that is thinner than the silicon crystal film 40f is formed. Alternatively, the ultra-thin silicon crystal film 40f disappears.

As described above, when the nitride semiconductor film 50fa formed at a low temperature is heated to 1080° C., lattice relaxation occurs. At this stage, even when the nitride semiconductor film 50fa is not fully relaxed and some strain remains therein, lattice relaxation further occurs during growth of the 2 μm nitride semiconductor film 50fb at a high temperature. Thus, a nitride semiconductor crystal layer is obtained in which the lattice stress and strain are relaxed. Then, a semiconductor device is completed by forming a second semiconductor layer 55 on the semiconductor wafer which is formed as described above.

In the present embodiment, before a gallium atom layer 11 is formed, the gallium atoms are diffused into the ultra-thin silicon crystal film 40f. Therefore, plastic deformation caused by occurrence of the dislocation 40t is likely to occur in the silicon crystal film 40f. It is known that gallium atoms diffuse while replacing the lattice positions in the silicon crystal. In the condition of the present embodiment, Ga atoms diffuse as far as the bottom portion of the silicon crystal film 40f of the thickness of 10 nm (the interface between the silicon crystal film 40f and the first layer 30). Therefore, the creation of the dislocation in the silicon crystal film 40f becomes easy. By the dislocation occurring in the silicon crystal film 40f, the stress accompanied by the growth of the nitride semiconductor films 50fa and 50fb is relaxed. Thus, the occurrence of crystal defects (dislocation) to the nitride semiconductor crystal (second region 50b) is suppressed, and it is possible that crystal quality is enhanced.

As described above, according to the embodiment, it is possible to provide a semiconductor device and a manufacturing method thereof, and a manufacturing method of a semiconductor wafer, in which crystal quality of a nitride semiconductor is enhanced.

In addition, in the embodiment, the semiconductor device may be a semiconductor light emitting device such as a laser diode (LD), a semiconductor light receiving device such as a photodiode (PD), or an electronic device such as a heterojunction bipolar transistor (HBT), a field effect transistor (FET), and a Schottky barrier diode (SBD).

In addition, in the present specification, a compound semiconductor is a generic term for semiconductor containing two or more elements included in, for example, III-V group (GaAs, GaN, InP, and the like), II-VI group (CdTe, ZnSe, CdS, and the like), IV-IV group (SiC, SiGe, and the like).

In addition, in the present specification, “nitride semiconductor” includes a III-V group compound semiconductor of BₓIn_{y}Al_{z}Ga_{1-x-y-z}N (0≦x≦1, 0≦y≦1, 0≦z≦1, 0≦x+y+z≦1), and includes a mixed crystal containing phosphorus (p), arsenic (AS), and the like in addition to nitrogen (N), as a V group element. Furthermore, it is assumed that those further containing various elements to be added for controlling various physical properties such as conductivity type and those further containing various elements which are contained unintentionally are included in the “nitride semiconductor”.

Hitherto, the embodiments have been described with reference to specific examples. However, the embodiments are not intended to be limited to the specific examples. For example, when those skilled in the art suitably select the specific configurations of respective elements such as the semiconductor layer, the first layer, and the substrate, from known ranges and the embodiment is carried out in the same manner, as long as the same effect is achieved, the configurations are assumed to be included in the scope of the embodiment.

Further, even if any two or more components in the specific examples are combined within a technically possible range, as long as the combination includes the spirit of the embodiment, the combination is assumed to be included in the scope of the embodiment.

In addition, all of the semiconductor device and the manufacturing method thereof, and the semiconductor wafer, which are performed by those skilled in the art appropriately modifying a design based on the semiconductor device and the manufacturing method thereof, and the semiconductor wafer, described above as the embodiments of the present invention also belong to the scope of the present invention, as long as they fall within the spirit of the invention.

In addition, those skilled in the art can conceive various variations and modifications in the scope of the concept of the present invention, and it is considered that variations and modifications belong to the scope of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer provided on a base and including a nitride semiconductor, the first semiconductor layer including a first region, and a second region which is provided on the first region, has a concentration of Si lower than a concentration of Si in the first region, and is thicker than the first region; and
a second semiconductor layer comprising a nitride semiconductor provided on the first semiconductor layer.

2. The device according to claim 1,
wherein a dislocation density of the first region is greater than a dislocation density of the second region.

3. The device according to claim 1, wherein the base includes
a substrate; and
a first layer comprising silicon oxide provided between the substrate and the first semiconductor layer.

4. The device according to claim 3,
wherein the substrate comprises polycrystalline AlN.

5. The device according to claim 1,
wherein the first region includes a Si crystal layer in contact with the base.

6. The device according claim 1,
wherein the concentration of Si in the first region is 1×10¹⁹ (atoms·cm⁻³) or more, and
wherein the concentration of Si in the second region is 1×10¹⁹ (atoms·cm⁻³) or less.

7. The device according to claim 1,
wherein a thickness of the first region is 5 nanometers or more and 500 nanometers or less, and
wherein a thickness of the second region is 50 nanometers or more and 10 micrometers or less.

8. The device according claim 1,
wherein each of the first region and the second region include GaN.

9. The device according to claim 1, wherein the difference between the coefficient of thermal expansion of the substrate and the second semiconductor layer is equal to, or less than, less than 3×10⁻⁶K⁻¹.

10. A semiconductor wafer comprising:
a base including a substrate, and a first layer comprising silicon oxide provided on the substrate; and
a first semiconductor layer comprising a nitride semiconductor provided on the first layer of the base, the first semiconductor layer including a first region containing silicon and a second region which is provided on the first region, has a concentration of Si lower than a concentration of Si in the first region, and is thicker than the first region.

11. The semiconductor wafer of claim 10, further comprising a third semiconductor layer disposed on the second semiconductor layer.

12. The semiconductor wafer of claim 11, wherein the difference between the coefficient of thermal expansion of the substrate and at least one of the second semiconductor layer and the third semiconductor layer is equal to, or less than, 3×10⁻⁶K¹.

13. The semiconductor wafer of claim 11, wherein the third semiconductor layer comprises gallium nitride.

14. The semiconductor wafer of claim 11, wherein the substrate comprises polycrystalline aluminum nitride.

15. The semiconductor wafer of claim 14, further comprising a silicon oxide layer interposed between the substrate and the first semiconductor layer.

16. A method of manufacturing a semiconductor device, comprising:
forming a silicon crystal film having a first thickness on a base including a substrate and a first layer provided on the substrate;
forming a first nitride semiconductor layer including a first region formed on the silicon crystal film and a second nitride semiconductor layer on the first layer; and
forming a second semiconductor layer including a nitride semiconductor on the first semiconductor layer,
wherein a concentration of Si in the first region is higher than a concentration of Si in the second region, and
wherein forming the first semiconductor layer includes
incorporating at least a portion of the silicon crystal film into the nitride semiconductor film, and
reducing the thickness of the silicon crystal film.

17. The method of claim 16, further comprising:
before forming the first semiconductor layer, terminating the surface of the silicon crystal film with hydrogen.

18. The method of claim 17, wherein the silicon crystal film is exposed to hydrofluoric acid to terminate the surface thereof.

19. The method of claim 16, wherein the substrate is heated to at least 600 C to incorporate at least a portion of the silicon crystal film into the nitride semiconductor film by inter-diffusion.

20. The method of claim 16, wherein the first layer of the base is a silicon oxide layer.
